(19) United States
(12) Patent Application Publication
(10) Pub. No.: US 2005/0051828 A1
(43) Pub. Date: Mar. 10, 2005

(54) Methods of forming metal thin films, lanthanum oxide films, and high dielectric films for semiconductor devices using atomic layer deposition

(76) Inventors: Ki-yeon Park, Gyeonggi-do (KR); Sung-tae Kim, Seoul (KR); Young-sun Kim, Gyeonggi-do (KR); In-sung Park, Seoul (KR); Jae-hyun Yeo, Gyeonggi-do (KR); Yun-jung Lee, Gainesville, FL (US); Ki-vin Im, Gyeonggi-do (KR)

Correspondence Address: MYERS BIGEL SIBLEY & SAJOVEC, PO BOX 37428, RALEIGH, NC, 27627, US

(21) Appl. No.: 10/828,596

(22) Filed: Apr. 21, 2004

(30) Foreign Application Priority Data
Apr. 22, 2003 (KR) 2003-0025533

(51) Int. Cl. H01B 1/00; H01L 27/108; H01L 29/94; H01L 31/119; H01L 21/31

(52) U.S. Cl. 257/310; 438/778; 438/785; 438/780

(57) ABSTRACT

The present invention provides methods of forming metal thin films, lanthanum oxide films and high dielectric films. Compositions of metal thin films, lanthanum oxide films and high dielectric films are also provided. Further provided are semiconductor devices comprising the metal thin films, lanthanum oxide films and high dielectric films provided herein.

### CROSS-REFERENCE TO RELATED APPLICATION

This application claims priority from Korean Patent Application No. 2003-25533, filed Apr. 22, 2003, the disclosure of which is incorporated herein by reference in its entirety.

### FIELD OF THE INVENTION

The present invention relates to semiconductor devices, and more particularly, to methods of forming films for use in semiconductor devices.

### BACKGROUND OF THE INVENTION

As the degree of integration of semiconductor devices increases, more capacitance per unit surface area may be desired in capacitors for Dynamic Random Access Memory (DRAM) devices. Hence, a method of increasing a surface area of a capacitor electrode by designing the electrode in a stack-type, a cylinder-type, a trench-type, or the like or by forming a hemispheric grain on the surface of the electrode has been suggested. A method for decreasing the thickness of a dielectric film as well as a method of using a high dielectric material or a ferroelectric material with a high dielectric constant as a dielectric film has been further suggested. Among these methods, the method of increasing the surface area of a capacitor electrode may provide limited applicability, if any, because the surface area of the electrode may have reached a possible maximal level. In the method of decreasing the thickness of a dielectric film, the capacitance increases with a decrease in the thickness of the film; however, an increase in leakage current may also result. Therefore, this method may provide limited utility. With respect to the method of using a high dielectric material for a dielectric film, in the case of using a high dielectric material with a high dielectric constant such as tantalum oxide (Ta₂O₅), titanium oxide (TiO₂), aluminum oxide (Al₂O₃), yttrium oxide (Y₂O₃), zirconium oxide (ZrO₂), and ((Ba, Sr)TiO₃) (BST), a problem can arise in that polysilicon, which has been currently used as an electrode material, can exhibit limited utility. As the thickness of a dielectric film decreases, tunneling may occur, and thus, a leakage current may increase contributing to the limited utility of polysilicon in the above-referenced method. In addition, the above-illustrated high dielectric materials may tend to react with polysilicon, whereby oxidation of polysilicon can occur or metal silicate can be generated. As a result, a problem can arise in that the generated dielectric film can serve as a low dielectric layer. In order to solve this problem, incorporation of a nitride film between the high dielectric film and the polysilicon film can be implemented.

As an example of one of the methods for increasing a capacitance per unit surface area of a capacitor, a metal-insulator-metal (MIM) capacitor using a metal such as titanium nitride (TiN) and platinum (Pt) with a high work function material as an electrode, instead of polycrystalline silicon, has been suggested. In the MIM capacitor, a metal oxide derived from a metal with a high oxygen affinity can be used as a dielectric film material. Examples of metal oxides currently used as a dielectric film material for the MIM capacitor include Ta₂O₅, Y₂O₃, hafnium oxide (HfO₂), niobium oxide. (Nb₂O₅), titanium oxide (TiO₂), barium oxide (BaO), strontium oxide (SrO), and BST.

Recent studies on lanthanum oxide (La₂O₃), which has a high dielectric constant of 27 and a thermodynamic stability with silicon at a relatively high temperature of about 1,000 K, revealed that La₂O₃ can have potential advantages as a metal oxide dielectric film material for a capacitor. It is known that La₂O₃ films have been formed using evaporation or chemical vapor deposition (CVD).

Actual application of the La₂O₃ film formed by evaporation or CVD to an integrated circuit may have several disadvantages. For example, in order to use the La₂O₃ film as a dielectric film for a capacitor, adequate step coverage and uniform deposition thickness should be secured even at a three dimensional structure with a high step difference. However, the La₂O₃ film formed by evaporation may have poor step coverage, and thus, may exhibit limited utility as a dielectric film for a capacitor. Also, in order to maintain high dielectric characteristics of the La₂O₃ film, the formation of a low dielectric layer between the La₂O₃ film and a lower electrode should be prevented. However, in the case of a polysilicon electrode, formation of the La₂O₃ film by CVD facilitates formation of lanthanum silicate at the interface between the La₂O₃ film and the polysilicon electrode, due to a high deposition temperature applied during the CVD. The formed lanthanum silicate serves as a low dielectric layer, thereby decreasing an electrostatic capacity.

### SUMMARY OF THE INVENTION

Embodiments according to the present invention can provide methods of forming metal thin films comprising forming an oxygen-deficient metal oxide film on a semiconductor substrate by atomic layer deposition (ALD) using an organic metal compound as a first reactant, wherein the oxygen-deficient metal oxide film comprises a metal oxide having an oxygen content that is less than a stoichiometric amount, and forming a metal oxide film on the oxygen-deficient metal oxide film by ALD using the first reactant and a second reactant comprising an oxidizing agent.

In other embodiments, the present invention can provide methods of forming lanthanum oxide films comprising forming a first lanthanum oxide film on a semiconductor substrate by atomic layer deposition (ALD) using an alkoxide-based organic metal compound as a first reactant, wherein the first lanthanum oxide film comprises La₂Oₓ wherein x<3, and forming a second lanthanum oxide film comprising La₂O₃ on the first lanthanum oxide film by ALD using the first reactant and a second reactant, wherein the second reactant comprises an oxidizing agent

Further embodiments of the present invention provide methods of forming high dielectric films comprising forming a first dielectric film on a semiconductor substrate, wherein the first dielectric film comprises a first metal oxide, and forming a second dielectric film on the first dielectric film, wherein the second dielectric film comprises a second metal oxide, and wherein the method of forming the second dielectric film comprises (a) forming an oxygen-deficient metal oxide film on the first dielectric film by atomic layer deposition (ALD) using an organic metal compound as a first reactant, wherein the oxygen-deficient metal oxide film comprises the second metal oxide and the second metal oxide has an oxygen content that is less than a stoichiometric amount, and (b) forming a metal oxide film on the oxygen-deficient metal oxide film by ALD using the first reactant and a second reactant comprising an oxidizing agent.

In some embodiments, methods of forming high dielectric films comprise forming a first dielectric film on a semiconductor substrate, wherein the first dielectric film comprises a metal oxide, and forming a second dielectric film on the first dielectric film, wherein the second dielectric film comprises a lanthanum oxide, and wherein the method of forming the second dielectric film comprises (a) forming a first lanthanum oxide film on a semiconductor substrate by atomic layer deposition (ALD) using an alkoxide-based organic metal compound as a first reactant, wherein the first lanthanum oxide film comprises La₂Oₓ wherein x<3, and (b) forming a second lanthanum oxide film comprising La₂O₃ on the first lanthanum oxide film by ALD using the first reactant and a second reactant, wherein the second reactant comprises an oxidizing agent.

Further embodiments of the present invention provide metal thin films, lanthanum oxide films and high dielectric films formed by the methods of the present invention. Additional embodiments of the present invention provide semiconductor devices comprising the metal thin films, lanthanum oxide films and high dielectric films described herein.

### BRIEF DESCRIPTION OF THE DRAWINGS

FIGS. 1A through 1D present sectional views that illustrate successive processes for methods of forming a high dielectric film according to some embodiments of the present invention;

FIGS. 2A and 2B illustrate gas pulsing diagrams that are applied in an atomic layer deposition (ALD) process for high dielectric film formation according to some embodiments of the present invention;

FIG. 3 presents a graph showing variation in deposition rate of a lanthanum oxide film with temperature in an ALD process;

FIGS. 4A and 4B present sectional views that illustrate methods of forming a high dielectric film according to some embodiments of the present invention; and

FIG. 5 presents a graph showing leakage current characteristics of the high dielectric film according to some embodiments of the present invention.

### DETAILED DESCRIPTION OF EMBODIMENTS ACCORDING TO THE INVENTION

The present invention will now be described more fully herein with reference to the accompanying drawings, in which embodiments of the invention are shown. This invention may, however, be embodied in many different forms and should not be construed as being limited to the embodiments set forth herein. Rather, these embodiments are provided so that this disclosure will be thorough and complete and will fully convey the concept of the invention to those skilled in the art.

The terminology used in the description of the invention herein is for the purpose of describing particular embodiments only and is not intended to be limiting of the invention. As used in the description of the embodiments of the invention and the appended claims, the singular forms “a”, “an” and “the” are intended to include the plural forms as well, unless the context clearly indicates otherwise.

Unless otherwise defined, all terms, including technical and scientific terms used in the description of the invention, have the same meaning as commonly understood by one of ordinary skill in the art to which this invention belongs. All publications, patent applications, patents, and other references mentioned herein are incorporated by reference in their entirety.

It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. It will be understood that relative terms are intended to encompass different orientations of the device in addition to the orientation depicted in the Figures.

Moreover, it will be understood that although the terms first and second are used herein to describe various compositions, features, elements, regions, layers and/or sections, these compositions, features, elements, regions, layers and/or sections should not be limited by these terms. These terms are only used to distinguish one composition, feature, element, region, layer or section from another compositions, feature, element, region, layer or section. Thus, a first composition, feature, element, region, layer or section discussed below could be termed a second composition, feature, element, region, layer or section, and similarly, a second without departing from the teachings of the present invention.

In the drawings, the thickness of layers and regions are exaggerated for clarity. It will also be understood that when a layer is referred to as being “on” another layer or substrate or a reactant is referred to as being feed “onto” another layer or substrate, it can be directly on the other layer or substrate, or intervening layers can also be present. However, when a layer, region or reactant is described as being “directly on” or feed “onto” another layer or region, no intervening layers or regions are present. Additionally, like numbers refer to like compositions or elements throughout.

As will be appreciated by one of skill in the art, the present invention may be embodied as compositions and devices as well as methods of making and using such compositions and devices.

In some embodiments, methods of forming metal thin films according to the present invention comprise, consist essentially of or consist of forming an oxygen-deficient metal oxide film on a semiconductor substrate by atomic layer deposition (ALD) using an organic metal compound as a first reactant, wherein the oxygen-deficient metal oxide film comprises a metal oxide having an oxygen content that is less than a stoichiometric amount, and forming a metal oxide film on the oxygen-deficient metal oxide film by ALD using the first reactant and a second reactant, wherein the second reactant comprises an oxidizing agent. In further embodiments, the first reactant can be an alkoxide-based metal oxide or a lanthanum-containing compound. In other embodiments, the first reactant can be tris(1-n-propoxy-2-methyl-2-propoxy)lanthanum (III) (La(NPMP)₃), tris(2-ethyl-1-n-propoxy-2-butoxy)lanthanum (III) (La(NPEB)₃), lanthanum (III) ethoxide (La(OCH₂H₅)₃), tris(6-ethyl-2,2-dimethyl-3,5-decanedionato)lanthanum (III) (La(EDMDD)₃), tris(dipivaloylmethanate)lanthanum (III) (La(DPM)₃), tris(2,2,6,6-tetramethyl-3,5-heptanedionato)lanthanum (III) (La(TMHD)₃), lanthanum (III) acetylacetonate (La(acac)₃), and tris(ethylcyclopentadienyl)lanthanum (III) (La(EtCp)₃), or combinations thereof. Methods of forming metal thin films can further comprise, consist essentially of or consist of (a) feeding the first reactant onto the semiconductor substrate to form an adsorbed layer of the first reactant, (b) removing a byproduct of (a) by means of purge, and (c) optionally repeating (a) and (b) until the oxygen-deficient metal oxide film with a predetermined thickness is formed. In some embodiments, the oxygen-deficient metal oxide film has a thickness in a range of about 5 Å to about 30 Å. Additionally, methods of forming metal thin films can further comprise, consist essentially of or consist of (a) feeding the first reactant onto the semiconductor substrate having the oxygen-deficient metal oxide film thereon, to form a chemisorbed layer of the first reactant, (b) feeding the second reactant onto the chemisorbed layer to form the metal oxide film; and (c) optionally repeating (a) and (b) until the metal oxide film with a predetermined thickness is formed. In some embodiments, the second reactant can be O₃, O₂, plasma O₂, H₂O, and N₂O, or combinations thereof. The methods of forming metal thin films can further comprise, consist essentially of or consist of removing a byproduct after (a) and removing a byproduct after (b). In some embodiments, the removal of the byproduct can be carried out by means of inert gas purge. In further embodiments, the methods described above can be carried out at a temperature in a range of about 200° C. to about 350° C. Additionally, the methods of forming thin metal films can further comprise, consist essentially of or consist of annealing the oxygen-deficient metal oxide film. The annealing can be carried out after forming the oxygen-deficient metal oxide film or after forming the metal oxide film. Moreover, the annealing can be carried out at a temperature in a range of about 300° C. to about 800° C. In some embodiments, the annealing can be carried out under an atmosphere of a gas, for example, O₂, N₂, and O₃, or combinations thereof, or under a vacuum atmosphere.

In further embodiments, the present invention provides methods of forming metal thin films capable of preventing the formation of a low dielectric layer at the interface between the metal thin film and a lower electrode. In some embodiments, the present invention provides a thin metal film formed by the methods described herein. Other embodiments of the present invention provide semiconductor devices including the thin metal films provided by the methods of the present invention.

In further embodiments, the present invention provides methods of forming lanthanum oxide films comprising, consisting essentially of or consisting of forming a first lanthanum oxide film on a semiconductor substrate by atomic layer deposition (ALD) using an alkoxide-based organic metal compound as a first reactant, wherein the first lanthanum oxide film comprises La₂Oₓ, wherein x<3, and forming a second lanthanum oxide film comprising La₂O₃ on the first lanthanum oxide film by ALD using the first reactant and a second reactant comprising an oxidizing agent. In some embodiments, the first reactant can be La(NPMP)₃, La(NPEB)₃, and La(OC₂H₅)₃, or combinations thereof. In other embodiments, methods of forming lanthanum oxide films can further comprise, consist essentially of or consist of (a) feeding the first reactant onto the semiconductor substrate to form an adsorbed layer of the first reactant, (b) removing a byproduct of (a) by means of purge, and (c) optionally repeating (a) and (b) until the first lanthanum oxide film with a predetermined thickness is formed. In some embodiments, the first lanthanum oxide film has a thickness in a range of about 5 Å to about 30 Å. Additionally, the methods of forming lanthanum oxide films can further comprise, consist essentially of or consist of (a) feeding the first reactant onto the semiconductor substrate having the first lanthanum oxide film thereon, to form a chemisorbed layer of the first reactant, (b) feeding the second reactant onto the chemisorbed layer to form the second lanthanum oxide film and (c) optionally repeating (a) and (b) until the second lanthanum oxide film with a predetermined thickness is formed. The second reactant can include O₃, O₂, plasma O₂, H₂O, and N₂O, or combinations thereof. In other embodiments, the methods of forming lanthanum oxide films can further comprise, consist essentially of or consist of removing a byproduct after (a) and removing a byproduct after (b). In some embodiments, the removal of the byproduct can be carried out by means of inert gas purge. In other embodiments, the method can be carried out at a temperature in a range of about 200° C. to about 350° C. Additionally, the methods of the present invention can further comprise, consist essentially of or consist of annealing the first lanthanum oxide film. The annealing can be carried out after forming the first lanthanum oxide film or after forming the second lanthanum oxide film. The annealing can be carried out at a temperature in a range of about 300° C. to about 800° C. Additionally, the annealing can be carried out under an atmosphere of a gas, for example, O₂, N₂, and 03, or combinations thereof, or under a vacuum atmosphere.

In further embodiments, the present invention provides methods of forming lanthanum oxide films having a uniform thickness and adequate step coverage on a lower electrode with a high step difference. In some embodiments, the present invention provides lanthanum oxide films formed by the methods of the present invention. Other embodiments of the present invention provide semiconductor devices including the lanthanum oxide films provided by the methods of the present invention.

Embodiments of the present invention further provide methods of forming high dielectric films comprising, consisting essentially of or consisting of forming a first dielectric film on a semiconductor substrate, wherein the first dielectric film comprises a first metal oxide, and forming a second dielectric film on the first dielectric film, wherein the second dielectric film comprises a second metal oxide, and wherein the method of forming the second dielectric film comprises (a) forming an oxygen-deficient metal oxide film on the first dielectric film by atomic layer deposition (ALD) using an organic metal compound as a first reactant, wherein the oxygen-deficient metal oxide film comprises the second metal oxide and the second metal oxide has an oxygen content that is less than a stoichiometric amount, and (b) forming a metal oxide film on the oxygen-deficient metal oxide film by ALD using the first reactant and a second reactant comprising an oxidizing agent. In some embodiments, the first dielectric film can be Al₂O₃. In other embodiments, the first dielectric film can be formed by chemical vapor deposition (CVD) or ALD. In further embodiments, the first dielectric film has a thickness in a range of about 30 Å to about 60 Å. In some embodiments, the first reactant includes an alkoxide-based metal oxide. In further embodiments, the methods of forming high dielectric films further comprise, consist essentially of or consist of (a) feeding the first reactant onto the first dielectric film to form an adsorbed layer of the first reactant, (b) removing a byproduct on the semiconductor substrate by means of purge and (c) optionally repeating (a) and (b). In some embodiments, the oxygen-deficient metal oxide film has a thickness in a range of about 5 Å to about 30 Å. In further embodiments, methods of forming high dielectric films further comprise, consist essentially of or consist of (a) feeding the first reactant onto the semiconductor substrate having the oxygen-deficient metal oxide film thereon, to form a chemisorbed layer of the first reactant, (b) feeding the second reactant onto the chemisorbed layer to form the metal oxide film and (c) optionally repeating (a) and (b). In some embodiments, the second reactant can include O₃, O₂, plasma O₂, H₂O, and N₂O, or combinations thereof. In further embodiments, methods of forming high dielectric films further comprise, consist essentially of or consist of removing a byproduct after forming the chemisorbed layer of the first reactant and removing a byproduct after forming the metal oxide film. The removal of the byproduct can be carried out by means of inert gas purge. In other embodiments, methods of forming high dielectric films can be carried out at a temperature in a range of about 200° C. to about 350° C. Additionally, the methods of forming high dielectric films can further comprise, consist essentially of or consist of annealing the oxygen-deficient metal oxide film. The annealing can be carried out after forming the oxygen-deficient metal oxide film or after forming the metal oxide film on the oxygen-deficient metal oxide film. The annealing can be carried out at a temperature in a range of about 300° C. to about 800° C. Additionally, the annealing can be carried out under an atmosphere of a gas, for example, O₂, N₂, and O₃, or combinations thereof, or under a vacuum atmosphere.

Embodiments of the present invention further provide methods of forming high dielectric films comprising, consisting essentially of or consisting of forming a first dielectric film on a semiconductor substrate, wherein the first dielectric film comprises a metal oxide, and forming a second dielectric film on the first dielectric film, wherein the second dielectric film comprises a lanthanum oxide, and wherein the method of forming the second dielectric film comprises (a) forming a first lanthanum oxide film on a semiconductor substrate by atomic layer deposition (ALD) using an alkoxide-based organic metal compound as a first reactant, wherein the first lanthanum oxide film comprises La₂Oₓ, wherein x<3, and (b) forming a second lanthanum oxide film comprising La₂O₃ on the first lanthanum oxide film by ALD using the first reactant and a second reactant comprising an oxidizing agent. In some embodiments, the first dielectric film includes Al₂O₃. In other embodiments, the first dielectric film can be formed by CVD or ALD. In some embodiments, the first dielectric film has a thickness of about 30 Å to about 60 Å. In other embodiments, the first reactant can be La(NPMP)₃, La(NPEB)₃, La(OCH₂H₅)₃, La(EDMDD)₃, La(DPM)₃, La(TMHD)₃, La(acac)₃, and La(EtCp)₃, or combinations thereof. In some embodiments, methods of forming the first lanthanum oxide films can further comprise, consist essentially of or consist of feeding the first reactant onto the first dielectric film to form an adsorbed layer of the first reactant, removing a byproduct on the semiconductor substrate by means of purge and optionally repeating (a) and (b) recited above. In other embodiments, the first lanthanum oxide film has a thickness in a range of about 5 Å to about 30 Å. In some embodiments, methods of forming the second lanthanum oxide film comprise, consist essentially of or consist of (a) feeding the first reactant onto the semiconductor substrate having the first lanthanum oxide film thereon, to form a chemisorbed layer of the first reactant, (b) feeding the second reactant onto the chemisorbed layer to form the second lanthanum oxide film and optionally repeating (a) and (b). The second reactant can include O₃, O₂, plasma O₂, H₂O, and N₂O, or combinations thereof. In some embodiments, methods of forming the second lanthanum oxide film further comprise, consist essentially of or consist of removing a byproduct after forming the chemisorbed layer of the first reactant and removing a byproduct after forming the second lanthanum oxide film. In further embodiments, removal of the byproduct can be carried out by means of inert gas purge. In other embodiments, forming the first lanthanum oxide film on a semiconductor substrate and forming a second lanthanum oxide film can be carried out at a temperature in a range of about 200° C. to about 350° C. In further embodiments, methods of forming high dielectric films further comprise, consist essentially of or consist of annealing the first lanthanum oxide film. The annealing can be carried out after forming the first lanthanum oxide film and after forming the second lanthanum film. Additionally, the annealing can be carried out at a temperature in a range of about 300° C. to about 800° C. In some embodiments, the annealing can be carried out under an atmosphere of a gas, for example, O₂, N₂, and O₃, or combinations thereof, or under a vacuum atmosphere.

In further embodiments, the present invention provides methods of forming high dielectric films capable of improving electric properties of a capacitor in semiconductor devices by forming a lanthanum oxide film having a high dielectric constant. In some embodiments, the present invention provides high dielectric films described herein. Other embodiments of the present invention provide semiconductor devices including the high dielectric films provided by the present invention.

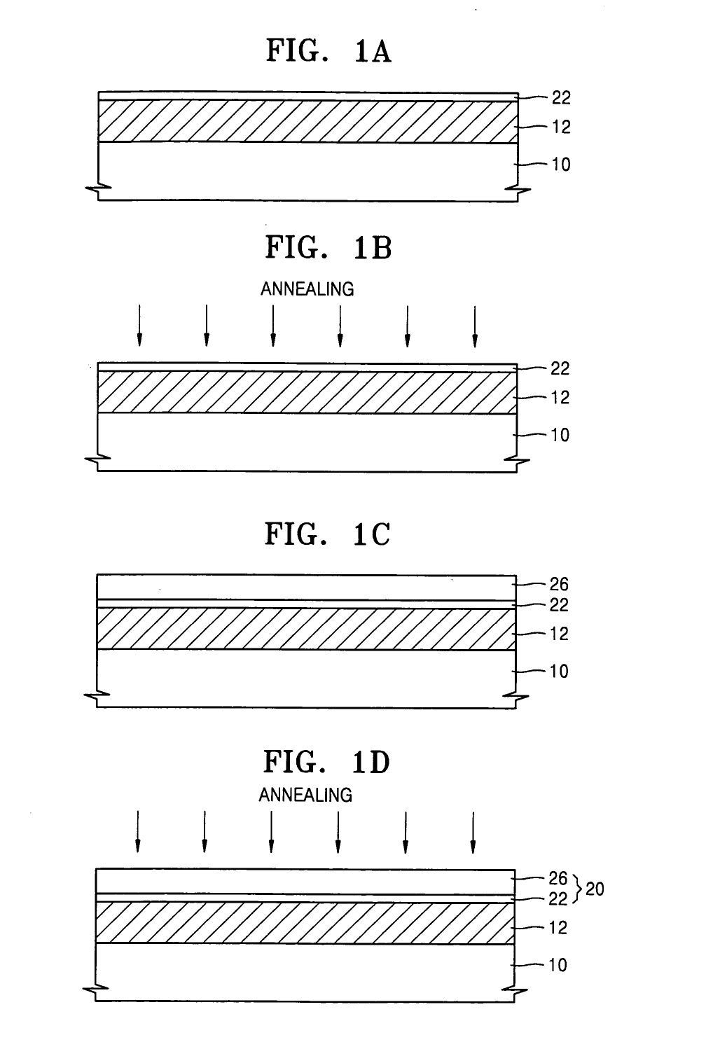

FIGS. 1A through 1D present sectional views that illustrate methods of forming a high dielectric film according to some embodiments of the present invention.

Referring to FIG. 1A, a lower electrode 12 can be formed on a semiconductor substrate 10. The lower electrode 12 may include a metal nitride or a noble metal. For example, the lower electrode 12 may include titanium nitride (TiN), tantalum nitride (TaN), tungsten (WN), ruthenium (Ru), iridium (Ir), platinum (Pt) or other similar materials. In the case of forming a non-MIM capacitor, the lower electrode 12 may also include doped polysilicon. In this instance, to reduce oxidation of the lower electrode 12 during a subsequent annealing process, a silicon nitride film can be formed on the lower electrode 12 by rapid thermal nitridation (RTN) of the surface of the lower electrode 12.

Subsequently, an oxygen-deficient metal oxide film 22 can be formed to a thickness of about 5 Å to about 30 Å on the lower electrode 12 using an organic metal compound as a first reactant by an atomic layer deposition (ALD) process. The ALD process for formation of the oxygen-deficient metal oxide film 22 can be carried out at a temperature in a range of about 200° C. to about 350° C.

The oxygen-deficient metal oxide film 22 can include a metal oxide with an oxygen content that is less than a stoichiometric amount. In the case of forming a high dielectric film including a lanthanum oxide, the oxygen-deficient metal oxide film 22 is a lanthanum oxide film having a composition of La₂Oₓ, wherein x<3.

Examples of the first reactant for formation of the oxygen-deficient metal oxide film 22 made of a lanthanum oxide include, but are not limited to, tris(1-n-propoxy-2-methyl-2-propoxy)lanthanum (III) (La(NPMP)₃), tris(2-ethyl-1-n-propoxy-2-butoxy)lanthanum (III) (La(NPEB)₃), lanthanum (III) ethoxide (La(OCH₂H₅)₃), tris(6-ethyl-2,2-dimethyl-3,5-decanedionato)lanthanum (III) (La(EDMDD)₃), tris(dipivaloylmethanate)lanthanum (III) (La(DPM)₃), tris(2,2,6,6-tetramethyl-3,5-heptanedionato)lanthanum (III) (La(TMHD)₃), lanthanum (III) acetylacetonate (La(acac)₃), and tris(ethylcyclopentadienyl)lanthanum (III) (La(EtCp)₃).

The first reactant can be an alkoxide-based metal oxide such as La(NPMP)₃, La(NPEB)₃, and La(OC₂H₅)₃. In some embodiments, the first reactant is La(NPMP)₃. In order to use solid La(NPMP)₃ in an ALD process for formation of high dielectric films according to embodiments of the present invention, first, La(NPMP)₃ can be dissolved in a solvent such as ethylcyclohexane and then fed into a vaporizer. The La(NPMP)₃ can be vaporized in the vaporizer and then fed into an ALD chamber.

The oxygen-deficient metal oxide film 22 can be formed using only the first reactant as a main source by ALD. That is, one ALD cycle for formation of the oxygen-deficient metal oxide 22 includes feeding the first reactant onto the semiconductor substrate 10 having the lower electrode 12 thereon, to form an adsorbed layer of the first reactant including a chemisorbed layer and a physisorbed layer and removing a byproduct on the semiconductor substrate 10 by means of inert gas purge. The oxygen-deficient metal oxide film 22 with a desired thickness can be formed by repeating one ALD cycle including the first reactant adsorption step and the inert gas purge step.

As described above, the oxygen-deficient metal oxide film 22 can be formed by using an organic metal compound such as a lanthanum source and a purge gas. By doing so, the oxidation of the lower electrode 12 can be reduced. Such oxidation can be reduced because an oxidizing agent is absent during the deposition for the formation of the oxygen-deficient metal oxide film 22. Also, the oxygen-deficient metal oxide film 22 can serve as a film for preventing the diffusion of a gaseous oxidizing agent used during a subsequent deposition process. Therefore, the oxidation of the lower electrode 12 can be prevented.

Referring to FIG. 1B, the oxygen-deficient metal oxide film 22 can be annealed under an oxygen-containing gas atmosphere or a vacuum atmosphere. Such annealing can be carried out for removing impurities, for example, carbon, which may be contained in the oxygen-deficient metal oxide film 22, but may be omitted in some embodiments. Such annealing may also be carried out after the completion of a subsequent high dielectric film deposition process, unlike the process presented in FIG. 1B. The annealing may be performed under a gas atmosphere such as O₂, N₂, or O₃, or combinations thereof. Annealing is carried out at a temperature in a range of about 300° C. to about 800° C.

Referring to FIG. 1C, a metal oxide film 26 can be formed on the oxygen-deficient metal oxide film 22 by ALD using the above first reactant and an oxidizing agent as a second reactant. The ALD process for the formation of the metal oxide film 26 can be carried out at a temperature in a range of about 200° C. to about 350° C.

In the case of forming a high dielectric film including a lanthanum oxide, the metal oxide film 26 can have a composition of La₂O₃. Examples of the first reactant for formation of the metal oxide film 26 including a lanthanum oxide include, but are not limited to, La(NPMP)₃, La(NPEB)₃, La(OCH₂H₅)₃, La(EDMDD)₃, La(DPM)₃, La(TMHD)₃, La(acac)₃, and La(EtCp)₃. The first reactant can be an alkoxide-based metal oxide, for example, La(NPMP)₃. As described previously with reference to FIG. 1B, La(NPMP)₃ can be fed into a vaporizer in a liquid state and then vaporized in the vaporizer before being fed into an ALD chamber. A lanthanum oxide film formed at a relatively low temperature in a range of about 200° C. to about 350° C. by ALD can have step coverage characteristics equal or superior to that formed by CVD. In addition, because a relatively low temperature can be used in the ALD process, formation of a low dielectric layer at the interface between the lower electrode 12 and the high dielectric film can be prevented. Also, because the first reactant, which can be an organic compound, and the second reactant, which can be an oxidizing agent, are alternately fed into a process chamber in the ALD process, the gas phase reaction of the organic metal compound fundamentally may not occur and the ALD can be carried out in a self-limiting manner by the surface reaction of the reactants. Therefore, a lanthanum oxide film formed by the ALD process having at least an adequate step coverage and good uniformity, even at a wide area, can result. In addition, precise film thickness control can be accomplished to a several A unit.

As noted above, the second reactant can be an oxidizing agent. The oxidizing agent may be O₃, O₂, plasma O₂, H₂O, N₂O or other similar materials. In some embodiments, by using O₃ as the second reactant, incorporation of impurities into the metal oxide film 26 can be reduced and step coverage of the metal oxide film 26 can be improved.

The metal oxide film 26 can be formed using the first and second reactants as a main source by ALD. Here, one ALD cycle for the formation of the metal oxide film 26 can include the following steps. The first reactant can be fed onto the semiconductor substrate 10 having the oxygen-deficient metal oxide film 22 thereon, to thereby form a chemisorbed layer of the first reactant. A byproduct of the reaction between the first reactant and the oxygen-deficient metal oxide film is removed by inert gas purge. After the byproduct removal, the second reactant can be fed onto the chemisorbed layer of the first reactant to form the metal oxide film. A byproduct of the reaction between the second reactant and the chemisorbed layer can be removed by inert gas purge. The one ALD cycle including the above-described steps can be repeated until the metal oxide film 26 with a desired thickness is formed.

As described previously with reference to FIG. 1B, in an embodiment wherein the annealing can be omitted immediately after the formation of the oxygen-deficient metal oxide film 22, the annealing can be carried out immediately after the formation of the metal oxide film 26, as shown in FIG. 1D. This completes the high dielectric film 20. The detailed description of the annealing is as described above with reference to FIG. 1B.

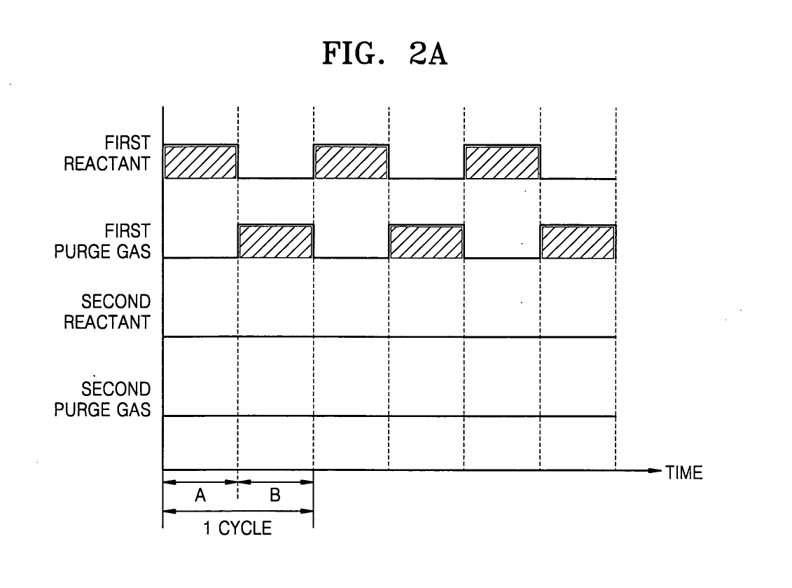

FIGS. 2A and 2B illustrate gas pulsing diagrams that are applied in the ALD process for high dielectric film formation according to embodiments of the present invention. In detail, FIG. 2A is a gas pulsing diagram that is applied in the ALD process for the formation of the oxygen-deficient metal oxide film 22 and FIG. 2B presents a gas pulsing diagram that is applied in the ALD process for the formation of the metal oxide film 26.

Referring to FIG. 2A, one ALD cycle for the formation of the oxygen-deficient metal oxide film 22 can include feeding the first reactant onto the semiconductor substrate 10 having the lower electrode 12 thereon, to form an adsorbed layer of the first reactant) and removing a byproduct thereof by means of purge with a first purge gas, i.e., an inert gas. These procedures can be repeated until the oxygen-deficient metal oxide film 22 with a predetermined thickness is formed. Here, the second reactant such as an oxidizing agent and a second purge gas for removal of a byproduct of the reaction using the second reactant is not required.

Referring to FIG. 2B, one ALD cycle for the formation of the metal oxide film 26 can include feeding the first reactant onto the semiconductor substrate 10 having the oxygen-deficient metal oxide film 22 thereon, to form a chemisorbed layer of the first reactant, removing a byproduct thereof by means of purge with the first purge gas, i.e., an inert gas, feeding the second reactant onto the chemisorbed layer of the first reactant to form the metal oxide film, and removing a byproduct thereof by means of purge with the second purge gas, i.e., an inert gas. These procedures can be repeated until the metal oxide film 26 with a predetermined thickness is formed.

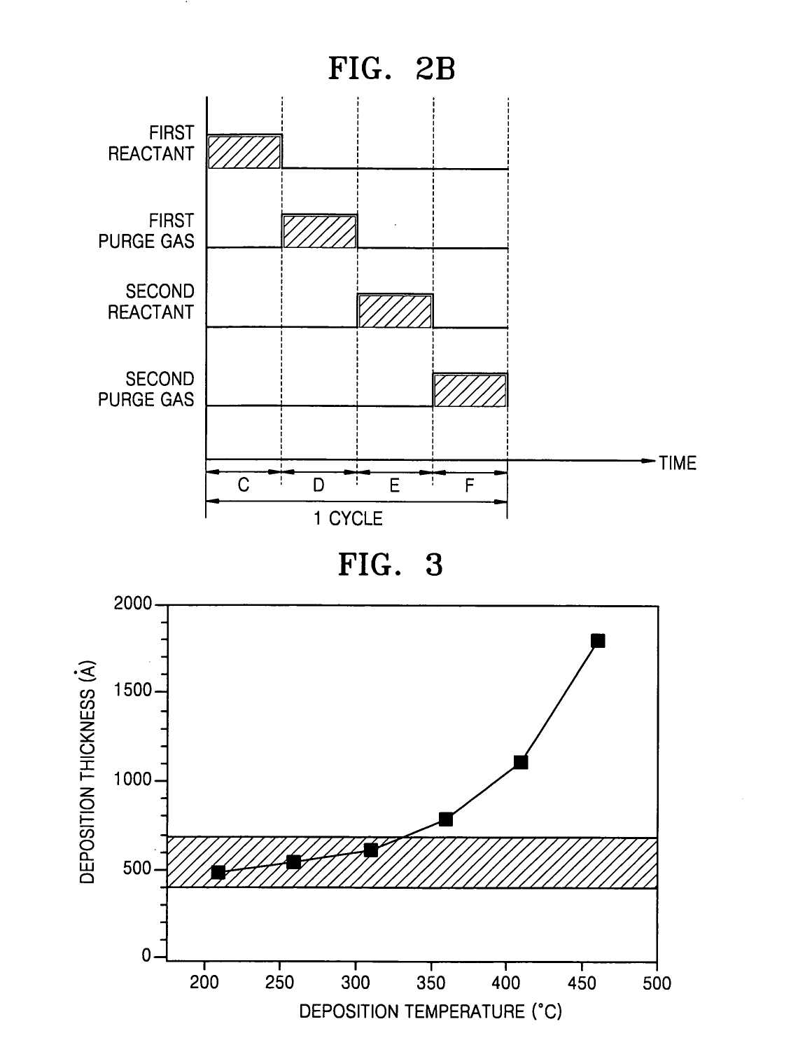

FIG. 3 depicts a graph showing variation in deposition rate of a lanthanum oxide film with temperature in an ALD process in order to evaluate the deposition rate of the lanthanum oxide film suitable for the high dielectric film formation method according to embodiments of the present invention.

For the evaluation of FIG. 3, a La₂O₃ film was formed by ALD according to the gas pulsing diagram as shown in FIG. 2B at various temperature conditions. Here, La(NPMP)₃ was used as the first reactant, O₃ as the second reactant, and argon (Ar) as the first and second purge gases. In each ALD cycle, formation of the metal oxide film, removing a byproduct thereof by means of purge with the first purge gas, i.e., an inert gas, feeding the second reactant onto the chemisorbed layer of the first reactant to form the metal oxide film, and removing a byproduct thereof by means of purge with the second purge gas, i.e., an inert gas, were carried out for 0.02, 5, 5, and 5 seconds, respectively. The thickness of the La₂O₃ film after total 100 cycles of ALD was measured.

According to the result shown in FIG. 3, the thickness of the La₂O₃ film slowly increased at a temperature in a range of about 200° C. to about 350° C., and thus, the deposition rate with an increase in deposition temperature is substantially constant. Meanwhile, at more than about 350° C., as the deposition temperature increases, the deposition rate may increase, in part, due to degradation of source gases. As shown in FIG. 3, the La₂O₃ film can be deposited by ALD at a temperature in a range of about 350° C. or less.

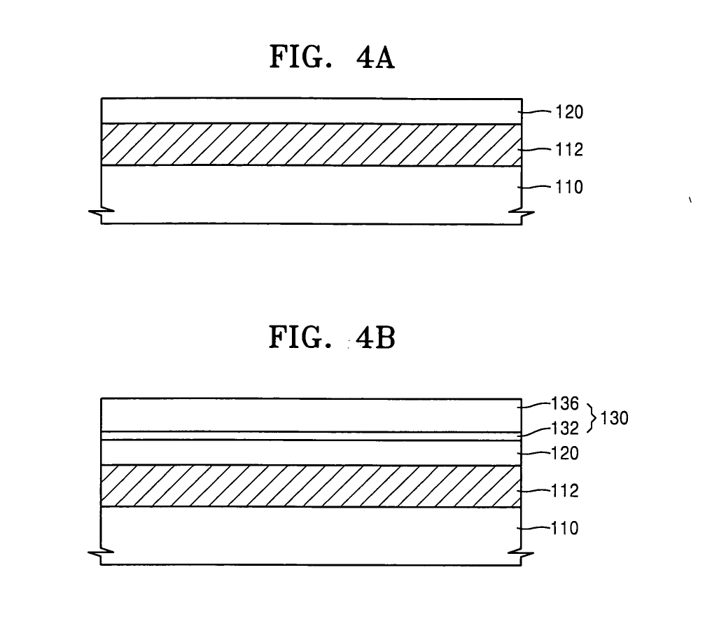

FIGS. 4A and 4B present sectional views that illustrate successive processes for a method of forming a high dielectric film according to embodiments of the present invention. In this particular embodiment, before forming an oxygen-deficient metal oxide film 132 on a lower electrode 112, a first dielectric film 120 including a material different from the material for the oxygen-deficient metal oxide film 132 can be further formed.

More specifically, referring to FIG. 4A, as described above with reference to FIG. 1A, a lower electrode 112 can be formed on a semiconductor substrate 110.

The first dielectric film 120 made of a first metal oxide can be formed on the lower electrode 112. The first dielectric film 120 can serve as an oxygen blocking film for preventing the oxidation of the lower electrode 112 during subsequent dielectric film annealing. In particular, in embodiments where the lower electrode 120 is made of a metal nitride or a noble metal, oxidation of the lower electrode 112, which may occur during the subsequent dielectric film annealing, can be prevented.

The first dielectric film 120 includes Al₂O₃. The first dielectric film 120 may be formed to a thickness of about 30 Å to about 60 Å.

The first dielectric film 120 may be formed by CVD or ALD. In the case of forming the first dielectric film 120 including Al₂O₃ using CVD, deposition may be performed using trimethyl aluminum (TMA) and H₂O at a temperature in a range of about 400° C. to about 500° C. under a pressure in a range of about 1 Torr to about 5 Torr.

In the case of forming the first dielectric film 120 including Al₂O₃ using ALD, deposition may be performed using TMA as a first reactant and O₃ as a second reactant at a temperature in a range of about 250° C. to about 400° C. under a pressure in a range of about 1 Torr to about 5 Torr. The deposition and purging processes can be repeated until an Al₂O₃ film with a desired thickness is formed. The first reactant for the formation of the Al₂O₃ film may be AlCl₃, AlH₃N(CH₃)₃, C₆H₁₅AlO, (C₄H₉)₂AlH, (CH₃)₂AlCl, (C₂H₅)₃Al, or (C₄H₉)₃Al, except for TMA. The second reactant may be H₂O, plasma N₂O, or plasma O₂, which can serve as an activated oxidizing agent.

Referring to FIG. 4B, a second dielectric film 130 including a second metal oxide can be formed on the first dielectric film 120. The second metal oxide is different from the first metal oxide, for example, a lanthanum oxide.

The second dielectric film 130 can be formed by sequentially depositing an oxygen-deficient metal oxide film 132 and a metal oxide film 136 on the first dielectric film 120, as described above with reference to FIGS. 1A through 1D. The detailed descriptions of the formation of the oxygen-deficient metal oxide film 132 and the metal oxide film 136 are as described above with reference to FIGS. 1A through 1D.

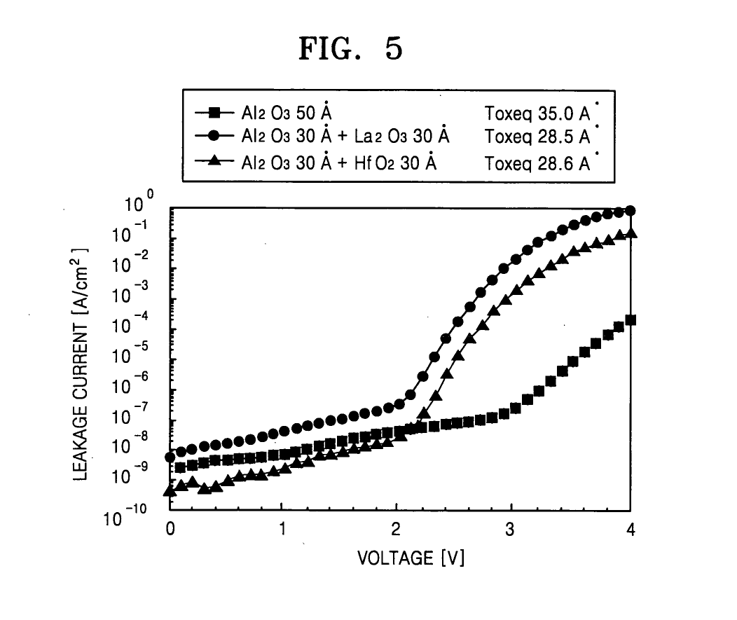

FIG. 5 depicts a graph showing an evaluation result (•) of leakage current characteristics of a high dielectric film having a dual film structure of the first dielectric film 120 and the second dielectric film 130 formed on the lower electrode 112 according to embodiments of the present invention.

For the evaluation of leakage current characteristics of FIG. 5, a first dielectric film including Al₂O₃ was formed to a thickness of about 30 Å on a lower electrode made of TiN and then a second dielectric film including La₂O₃ was formed to a thickness of about 30 Å on the first dielectric film. Here, a deposition temperature was set to about 300° C. A TiN upper electrode was formed on the Al₂O₃/La₂O₃ dual film and then photolithography and etching were performed to thereby complete a capacitor. The leakage current characteristics of the completed capacitor were evaluated.

As comparative examples, the leakage current characteristics of a dielectric film (▮) made of only Al₂O₃ with a thickness of about 50 Å and a dielectric film (▴) having a dual film structure of an Al₂O₃ film with a thickness of about 30 Å and a HfO₂ film with a thickness of about 30 Å are also shown in FIG. 5. Except for the above-described conditions, other conditions of the control examples were the same as in the case of embodiments of the present invention (•).

According to the results of FIG. 5, the high dielectric film including Al₂O₃/La₂O₃ according to embodiments of the present invention has a relatively low equivalent oxide film thickness (Toxeq) of about 28.5 Å, and thus, can exhibit high dielectric characteristics. In addition, the Al₂O₃/La₂O₃ dielectric film has a take-off voltage of about 2.0 V, which is similar to the take-off voltage of the Al₂O₃/HfO₂ dielectric film, and thus, exhibits good leakage current characteristics.

As apparent from the above description, the high dielectric film for a semiconductor device according to embodiments of the present invention can be formed using an organic metal compound as a metal source by ALD. In particular, in order to minimize the formation of a low dielectric layer at the interface between the lower electrode and the high dielectric film, at an early stage of the formation of the high dielectric film, the oxygen-deficient metal oxide film can be formed using an organic metal compound, such as an alkoxide-based organic metal compound, as a main source by ALD. Thereafter, in order to prevent the incorporation of impurities into the high dielectric film and improve step coverage, the metal oxide film can be formed on the oxygen-deficient oxide film using an organic metal compound and an oxidizing agent as a main source.

The metal oxide films deposited by ALD according to embodiments of the present invention can have equal or superior step coverage and can be formed at a lower deposition temperature, when compared to a thin film deposited by CVD. Therefore, the formation of a low dielectric layer between the lower electrode and the high dielectric film can be prevented. Also, because a metal source and an oxidizing agent are alternately fed into an ALD process chamber, the gas phase reaction of the metal source may not occur and the ALD can be carried out in a self-limiting manner by the reaction of the surface saturated with the sources fed into the process chamber. Therefore, the metal oxide films formed by the ALD process can have at least adequate step coverage and good uniformity even at a wide area. In addition, precise film thickness control of a fine unit level can be accomplished.

Therefore, according to embodiments of the present invention, high dielectric films with at least adequate step coverage and uniform thickness can be formed on a lower electrode with high step difference by a three dimensional structure. In addition, because the formation of a low dielectric layer can be prevented by forming a metal oxide film with a high dielectric constant, the electric properties of a capacitor can be improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method of forming a metal thin film, comprising:
forming an oxygen-deficient metal oxide film on a semiconductor substrate by atomic layer deposition (ALD) using an organic metal compound as a first reactant, wherein the oxygen-deficient metal oxide film comprises a metal oxide having an oxygen content that is less than a stoichiometric amount; and
forming a metal oxide film on the oxygen-deficient metal oxide film by ALD using the first reactant and a second reactant, wherein the second reactant comprises an oxidizing agent.

2. The method according to claim 1, wherein the first reactant comprises an alkoxide-based metal oxide.

3. The method according to claim 1, wherein the first reactant comprises a lanthanum-containing compound.

4. The method according to claim 3, wherein the first reactant is selected from the group consisting of tris(1-n-propoxy-2-methyl-2-propoxy)lanthanum (III) (La(NPMP)₃), tris(2-ethyl-1-n-propoxy-2-butoxy)lanthanum (III) (La(NPEB)₃), lanthanum (III) ethoxide (La(OCH₂H₅)₃), tris(6-ethyl-2,2-dimethyl-3,5-decanedionato)lanthanum (III) (La(EDMDD)₃), tris(dipivaloylmethanate)lanthanum (III) (La(DPM)₃), tris(2,2,6,6-tetramethyl-3,5-heptanedionato)lanthanum (III) (La(TMHD)₃), lanthanum (III) acetylacetonate (La(acac)₃), and tris(ethylcyclopentadienyl)lanthanum (III) (La(EtCp)₃), or combinations thereof.

5. The method according to claim 1 further comprising:
(a) feeding the first reactant onto the semiconductor substrate to form an adsorbed layer of the first reactant;
(b) removing a byproduct of (a) by means of purge; and
(c) optionally repeating (a) and (b) until the oxygen-deficient metal oxide film with a predetermined thickness is formed.

6. The method according to claim 1, wherein the oxygen-deficient metal oxide film has a thickness in a range of about 5 Å to about 30 Å.

7. The method according to claim 1, further comprising:
(a) feeding the first reactant onto the semiconductor substrate having the oxygen-deficient metal oxide film thereon, to form a chemisorbed layer of the first reactant;
(b) feeding the second reactant onto the chemisorbed layer to form the metal oxide film; and
(c) optionally repeating (a) and (b) until the metal oxide film with a predetermined thickness is formed.

8. The method according to claim 7, wherein the second reactant is selected from the group consisting of O₃, O₂, plasma O₂, H₂O, and N₂O, or combinations thereof.

9. The method according to claim 7, further comprising removing a byproduct after (a) and removing a byproduct after (b).

10. The method according to claim 9, wherein the removal of the byproduct is carried out by means of inert gas purge.

11. The method according to claim 1, wherein the method is carried out at a temperature in a range of about 200° C. to about 350° C.

12. The method according to claim 1 further comprising annealing the oxygen-deficient metal oxide film.

13. The method according to claim 12, wherein the annealing is carried out after forming the oxygen-deficient metal oxide film or after forming the metal oxide film.

14. The method according to claim 12, wherein the annealing is carried out at a temperature in a range of about 300° C. to about 800° C.

15. The method according to claim 12, wherein the annealing is carried out under an atmosphere of a gas selected from the group consisting of O₂, N₂, and 03, or combinations thereof, or under a vacuum atmosphere.

16. A method of forming a lanthanum oxide film, comprising:
forming a first lanthanum oxide film on a semiconductor substrate by atomic layer deposition (ALD) using an alkoxide-based organic metal compound as a first reactant, wherein the first lanthanum oxide film comprises La₂Ox wherein x<3; and
forming a second lanthanum oxide film comprising La₂O₃ on the first lanthanum oxide film by ALD using the first reactant and a second reactant, wherein the second reactant comprises an oxidizing agent.

17. The method according to claim 16, wherein the first reactant is selected from the group consisting of La(NPMP)₃, La(NPEB)₃, and La(OC₂H₅)₃, or combinations thereof.

18. The method according to claim 16 further comprising:
(a) feeding the first reactant onto the semiconductor substrate to form an adsorbed layer of the first reactant;
(b) removing a byproduct of (a) by means of purge; and
(c) optionally repeating (a) and (b) until the first lanthanum oxide film with a predetermined thickness is formed.

19. The method according to claim 18, wherein the first lanthanum oxide film has a thickness in a range of about 5 Å to about 30 Å.

20. The method according to claim 16 further comprising:
(a) feeding the first reactant onto the semiconductor substrate having the first lanthanum oxide film thereon, to form a chemisorbed layer of the first reactant;
(b) feeding the second reactant onto the chemisorbed layer to form the second lanthanum oxide film; and
(c) optionally repeating (a) and (b) until the second lanthanum oxide film with a predetermined thickness is formed.

21. The method according to claim 20, wherein the second reactant is selected from the group consisting of O₃, O₂, plasma O₂, H₂O, and N₂O, or combinations thereof.

22. The method according to claim 20, further comprising removing a byproduct after (a) and removing a byproduct after (b).

23. The method according to claim 22, wherein the removal of the byproduct is carried out by means of inert gas purge.

24. The method according to claim 16, wherein the method is carried out at a temperature in a range of about 200° C. to about 350° C.

25. The method according to claim 16 further comprising annealing the first lanthanum oxide film.

26. The method according to claim 25, wherein the annealing is carried out after forming the first lanthanum oxide film or after forming the second lanthanum oxide film.

27. The method according to claim 25, wherein the annealing is carried out at a temperature in a range of about 300° C. to about 800° C.

28. The method according to claim 25, wherein the annealing is carried out under an atmosphere of a gas selected from the group consisting of O₂, N₂, and O₃, or combinations thereof, or under a vacuum atmosphere.

29. A method of forming a high dielectric film, comprising:
forming a first dielectric film on a semiconductor substrate, wherein the first dielectric film comprises a first metal oxide; and
forming a second dielectric film on the first dielectric film, wherein the second dielectric film comprises a second metal oxide, and wherein the method of forming the second dielectric film comprises:
(a) forming an oxygen-deficient metal oxide film on the first dielectric film by atomic layer deposition (ALD) using an organic metal compound as a first reactant, wherein the oxygen-deficient metal oxide film comprises the second metal oxide and the second metal oxide has an oxygen content that is less than a stoichiometric amount; and
(b) forming a metal oxide film on the oxygen-deficient metal oxide film by ALD using the first reactant and a second reactant, wherein the second reactant comprises an oxidizing agent.

30. The method according to claim 29, wherein the first dielectric film comprises Al₂O₃.

31. The method according to claim 29, wherein the first dielectric film is formed by chemical vapor deposition (CVD) or ALD.

32. The method according to claim 29, wherein the first dielectric film has a thickness in a range of about 30 Å to about 60 Å.

33. The method according to claim 29, wherein the first reactant comprises an alkoxide-based metal oxide.

34. The method according to claim 29, wherein forming the oxygen-deficient metal oxide film comprises:
(a) feeding the first reactant onto the first dielectric film to form an adsorbed layer of the first reactant;
(b) removing a byproduct on the semiconductor substrate by means of purge;
and(c) optionally repeating (a) and (b).

35. The method according to claim 29, wherein the oxygen-deficient metal oxide film has a thickness in a range of about 5 Å to about 30 Å.

36. The method according to claim 29, wherein forming the metal oxide film comprises:
(a) feeding the first reactant onto the semiconductor substrate having the oxygen-deficient metal oxide film thereon, to form a chemisorbed layer of the first reactant;
(b) feeding the second reactant onto the chemisorbed layer to form the metal oxide film; and
(c) optionally repeating (a) and (b).

37. The method according to claim 36, wherein the second reactant is selected from the group consisting of O₃, O₂, plasma O₂, H₂O, and N₂O, or combinations thereof.

38. The method according to claim 36, further comprising removing a byproduct after forming the chemisorbed layer of the first reactant and removing a byproduct after forming the metal oxide film.

39. The method according to claim 38, wherein the removal of the byproduct is carried out by means of inert gas purge.

40. The method according to claim 29, wherein (a) and (b) are carried out at a temperature in a range of about 200° C. to about 350° C.

41. The method according to claim 29 further comprising annealing the oxygen-deficient metal oxide film.

42. The method according to claim 41, wherein the annealing is carried out after forming the oxygen-deficient metal oxide film or after forming the metal oxide film on the oxygen-deficient metal oxide film.

43. The method according to claim 41, wherein the annealing is carried out at a temperature in a range of about 300° C. to about 800° C.

44. The method according to claim 41, wherein the annealing is carried out under an atmosphere of a gas selected from the group consisting of O₂, N₂, and O₃, or combinations thereof, or under a vacuum atmosphere.

45. A method of forming a high dielectric film, comprising:
forming a first dielectric film on a semiconductor substrate, wherein the first dielectric film comprises a metal oxide; and
forming a second dielectric film on the first dielectric film, wherein the second dielectric film comprises a lanthanum oxide, and wherein the method of forming the second dielectric film comprises:
(a) forming a first lanthanum oxide film on a semiconductor substrate by atomic layer deposition (ALD) using an alkoxide-based organic metal compound as a first reactant, wherein the first lanthanum oxide film comprises La₂Oₓ, wherein x<3; and
(b) forming a second lanthanum oxide film comprising La₂O₃ on the first lanthanum oxide film by ALD using the first reactant and a second reactant, wherein the second reactant comprises an oxidizing agent.

46. The method according to claim 45, wherein the first dielectric film comprises Al₂O₃.

47. The method according to claim 45, wherein the first dielectric film is formed by CVD or ALD.

48. The method according to claim 45, wherein the first dielectric film has a thickness in a range of about 30 Å to about 60 Å.

49. The method according to claim 45, wherein the first reactant is selected from the group consisting of La(NPMP)₃, La(NPEB)₃, La(OCH₂H₅)₃, La(EDMDD)₃, La(DPM)₃, La(TMHD)₃, La(acac)₃, and La(EtCp)₃, or combinations thereof.

50. The method according to claim 45, wherein the method of forming the first lanthanum oxide film comprises:
feeding the first reactant onto the first dielectric film to form an adsorbed layer of the first reactant;
removing a byproduct on the semiconductor substrate by means of purge; and
optionally repeating (a) and (b).

51. The method according to claim 45, wherein the first lanthanum oxide film has a thickness in a range of about 5 Å to about 30 Å.

52. The method according to claim 45, wherein the method of forming the second lanthanum oxide film comprises:
(a) feeding the first reactant onto the semiconductor substrate having the first lanthanum oxide film thereon, to form a chemisorbed layer of the first reactant;
(b) feeding the second reactant onto the chemisorbed layer to form the second lanthanum oxide film; and
optionally repeating (a) and (b).

53. The method according to claim 52, wherein the second reactant is selected from the group consisting of O₃, O₂, plasma O₂, H₂O, and N₂O, or combinations thereof.

54. The method according to claim 52, further comprising removing a byproduct after forming the chemisorbed layer of the first reactant and removing a byproduct after forming the second lanthanum oxide film.

55. The method according to claim 54, wherein removal of the byproduct is carried out by means of inert gas purge.

56. The method according to claim 45, wherein (a) and (b) are carried out at a temperature in a range of about 200° C. to about 350° C.

57. The method according to claim 45 further comprising annealing the first lanthanum oxide film.

58. The method according to claim 57, wherein the annealing is carried out after forming the first lanthanum oxide film and after forming the second lanthanum oxide film.

59. The method according to claim 57, wherein the annealing is carried out at a temperature in a range of about 300° C. to about 800° C.

60. The method according to claim 57, wherein the annealing is carried out under an atmosphere of a gas selected from the group consisting of O₂, N₂, and O₃, or combinations thereof, or under a vacuum atmosphere.

61. A metal thin film formed by the method according to claim 1.

62. The metal thin film according to claim 61, wherein the metal thin film is capable of preventing the formation of a low dielectric layer at an interface between the metal thin film and an electrode.

63. A semiconductor device comprising the metal thin film according to claim 61.

64. A lanthanum oxide film formed by the method according to claim 16.

65. A semiconductor device comprising the lanthanum oxide film according to claim 64.

66. A high dielectric film formed by the method according to claim 29.

67. A semiconductor device comprising the high dielectric film according to claim 66.

68. A high dielectric film formed by the method according to claim 45.

69. A semiconductor device comprising the high dielectric film according to claim 68.
